(19) United States
(12) Patent Application Publication
(10) Pub. No.: US 2008/0178066 A1
(43) Pub. Date: Jul. 24, 2008

(54) Method and apparatus for receiving data in communication system

(75) Inventors: Sung-Wook Kim, Seoul (KR); June Moon, Seoul (KR)

Correspondence Address: DOCKET CLERK, P.O. DRAWER 800889, DALLAS, TX, 75380, US

(73) Assignee: Samsung Electronics Co., Ltd., Suwon-si (KR)

(21) Appl. No.: 12/009,435

(22) Filed: Jan. 18, 2008

(30) Foreign Application Priority Data
Jan. 18, 2007 (KR) 2007-5663

(51) Int. Cl. H03M 13/00

(52) U.S. Cl. 714/807

(57) ABSTRACT

Disclosed is an apparatus for receiving data in a communication system, the apparatus including: a first memory for receiving data and storing input messages (i.e. V2C messages) of respective check nodes in a low-density parity check (LDPC) matrix of the received data; a second memory for storing a summation value of all the input messages of the check nodes; and a decoder for subtracting the input messages of the respective check nodes from the summation value, and updating input messages of respective variable nodes corresponding to the check nodes.

### CROSS-REFERENCE TO RELATED APPLICATION(S) AND CLAIM OF PRIORITY

This application claims priority to application entitled “Method And Apparatus For Receiving Data In Communication System” filed with the Korean Intellectual Property Office on Jan. 18, 2007 and assigned Serial No. 2007-5663, the contents of which are incorporated herein by reference.

### TECHNICAL FIELD OF THE INVENTION

The present invention relates to a method and apparatus for receiving data in a communication system using a low-density parity check (LDPC) code.

### BACKGROUND OF THE INVENTION

The LDPC code, first provided by Gallager and restudied by MacKay, has recently attracted attention as a code that can show superior performance approaching the Shannon's capacity limit by belief propagation decoding based on a sum-product algorithm.

Thereafter, Richardson et al. proposed a density evolution technique that pursues a variation according to iteration in probability distribution of messages generated and updated during a decoding process in a factor graph constituting an LDPC code. In addition, using the density evolution technique, Richardson et al. proposed degree distribution of variable and check nodes in a factor graph, which can maximize a channel parameter (for example, threshold) capable of making error probability converge at 0 on the assumption of infinite iteration in a cycle-free factor graph. Further, Richardson et al. has theoretically shown that such a case can be applied even to a finite-length LDPC code having cycles. Richardson et al. also has shown that theoretical channel capacity of an irregular LDPC code can approach the Shannon's capacity limit by up to 0.0045 dB with the use of the density evolution technique.

Meanwhile, the LDPC code may increase in complexity of a coding and decoding process because its performance increases as a packet size increases. Recently, Flarion Company has proposed a multi-edge type vector LDPC code that can be implemented at low hardware complexity, even for a large packet size. The vector LDPC code, for example, Block LDPC (BLDPC) code, is a code for which an efficient coder and decoder can be implemented through parallel implementation of a vectorized structure, even with a small-sized base H matrix, for example, a check matrix. The parallel implementation due to parallel factors of the BLDPC code is being discussed as a possible alternative to the base codes in the next generation mobile communication system in which a data rate increases sharply, because the BLDPC code, compared with other codes, for example, turbo code and convolutional code, enables implementation of a higher-throughput decoder.

The LDPC code is a special case of the general linear block codes, and is defined as a parity check matrix. Hereinafter, a parity check matrix of an LDPC code will be described with reference to FIG. 1.

FIG. 1 is a view illustrating a parity check matrix of a general LDPC code.

The parity check matrix “H” of the LDPC code includes eight columns and four rows, in which the eight columns correspond to variable nodes v₁, v₂, v₃, v₄, v₅, v₆, v₇ and v₈, and the four rows correspond to check nodes c₁, c₂, c₃ and c₄.

FIG. 2 is a view illustrating a bipartite graph of the LDPC code shown in FIG. 1.

The bipartite graph of the LDPC code includes eight variable nodes v₁ 201, v₂ 203, v₃ 205, v₄ 207, v₅ 209, v₆ 211, v₇ 213, and v₈ 215, and the four check nodes c₁ 221, c₂ 223, c₃ 225, and c₄ 227. When an element having a value other than “0” exists at a place where a j^{th} column and an i^{th} row cross each other in the parity check matrix of the LDPC code, as shown in FIG. 1, an edge is generated between a j^{th} variable node vⱼ and an i^{th} check node cᵢ.

FIG. 3 is a view explaining input and output messages of a variable node in the bipartite graph of the LDPC code. FIG. 3 illustrates the input and output messages of the variable node v₁ when an edge is generated between one of multiple variable nodes, that is, variable node v₁ and three check nodes c₁, c₂ and c₃.

The input messages 300 to of the variable node v₁ 301 include edge messages m_{1,1}^{c2v}, m_{2,1}^{c2v} and m_{3,1}^{c2v} transmitted from check nodes c₁ 311, c₂ 313 and c₃ 315 through the edge, and an a priori log likelihood ratio (LLR) y₁ corresponding to the variable node v₁ 301 itself. When receiving the input messages 300, as described above, the variable node v₁ 301 performs an update operation, and then outputs output messages. That is, the output messages 350 of the variable node v₁ 301 include edge messages m_{1,1}^{v2c}, m_{1,2}^{v2c} and m_{1,3}^{v2c} transmitted to the check nodes c₁ 311, c₂ 313 and c₃ 315 through the edge, and a bit value ŷ₁ decoded in the variable node v₁ 301.

FIG. 4 is a view explaining input and output messages of a check node in the bipartite graph of the LDPC code. FIG. 4 illustrates the input and output messages of check node c₁ when an edge is generated between one of multiple check nodes, that is, the check node c₁ and three variable nodes v₁, v₂ and v₃.

The input messages 400 of the check node c₁ 401 include edge messages m_{1,1}^{v2c}, m_{2,1}^{v2c} and m_{3,1}^{v2c} transmitted from variable nodes v₁ 411, v₂ 413 and v₃ 415 through the edge. When receiving the input messages 400, as described above, the check node c₁ 401 performs an update operation, and then outputs output messages. That is, the output messages 450 of the check node c₁ 401 include edge messages m_{1,1}^{c2v}, m_{1,2}^{c2v} and m_{1,3}^{c2v} transmitted to the check nodes v₁ 411, v₂ 413 and v₃ 415 through the edge. The following description will be given about a procedure of performing an update operation with respect to all variable nodes and check nodes having a value of “1” in the parity check matrix “H” of the LDPC code, and of outputting output messages when messages are input to variable nodes and check nodes.

First of all, variables to be used in the following description are defined as follows: 1) yᵢ represents an a priori LLR corresponding to an i^{th} variable node (i^{th} reception bit); 2) ŷᵢ represents a bit value decoded in an i^{th} variable node; 3) C(i) represents an index set of variable nodes connected to an i^{th} variable node; 4) C(j) represents an index set of check nodes connected to a j^{th} check node; 5) m_{i,j}^{v2c} represents an edge message transmitted from an i^{th} variable node to a j^{th} check node; 6) m_{j,i}^{c2v} represents an edge message transmitted from a j^{th} check node to an i^{th} variable node;

$$F ( x ) \text{:} log \frac{1 + {e}^{- x}}{1 - {e}^{- x}} ;$$

$${F}^{- 1} ( x ) \text{:} {( log \frac{1 + {e}^{- x}}{1 - {e}^{- x}} )}^{- 1} ; and$$

Pᵢ^{llr} represents an a posteriori LLR of an i^{th} variable node.

Then, message m_{i,j}^{v2c} input to a check node and message m_{j,i}^{c2v} input to a variable node are initialized, and may be expressed as Equation 1.

m_{i,j}^{v2c}=yᵢ, m_{j,i}^{c2v}=0 [Eqn. 1]

Next, when each input message is input to the check node and variable node, an update operation is performed, and output messages m_{i,j}^{v2c} and m_{j,i}^{c2v} are output, as expressed in Equations 2 and 3.

$$\begin{matrix}{m}_{j , i}^{c 2 v} = ( {\prod }_{k ∈ C ( j )} sign ( {m}_{j , k}^{v 2 c} ) \cdot sign ( {m}_{j , i}^{v 2 c} ) ) \cdot ( {F}^{- 1} ( ( {\sum }_{k ∈ C ( j )} F ( {m}_{j , k}^{v 2 c} ) ) - F ( {m}_{j , i}^{v 2 c} ) ) ) . & [ Eqn . 2 ] \\ {m}_{i , j}^{v 2 c} = {y}_{i} + ( {\sum }_{k ∈ C ( j )} {m}_{k , i}^{c 2 v} ) ) - {m}_{j , i}^{c 2 v} . & [ Eqn . 3 ]\end{matrix}$$

In Equation 2, the sign represents the sign of a corresponding message, and expresses “+1” or “−1.” In this case, the update operation for the variable node and check node is performed with respect to all variable nodes and check nodes where the parity check matrix “H” of the LDPC code has a value of “1,” as described above.

An a posteriori LLR Pᵢ^{llr} output from each variable node through such an update may be expressed as Equation 4 below:

$${P}_{i}^{llr} = {y}_{i} + {\sum }_{k ∈ C ( i )} {m}_{k , j}^{c 2 v} . \qquad [ Eqn . 4 ]$$

When the a posteriori LLR Pᵢ^{llr} expressed in Equation 4 has a value less than “0,” the decoded bit value ŷᵢ has a value of 1, and when the a posteriori LLR Pᵢ^{llr} has a value equal to or greater than zero, the decoded bit value ŷᵢ has a value of “0.” The update operations of the variable node and check node, that is, Equations 2 and 3 will now be described in more detail with reference to FIGS. 3 and 4.

First, the output message m_{i,j}^{v2c} of a variable node, expressed in Equation 3, will be described with reference to FIG. 3. Since the input messages 300 of the variable node v₁ 301 include m_{1,1}^{c2v}, m_{2,1}^{c2v} and m_{3,1}^{c2v} input from check nodes c₁ 311, c₂ 313 and c₃ 315 through an edge, and an a priori LLR y₁ corresponding to the variable node v₁ 301 itself, as shown in FIG. 3, the messages 350 output after an update has been performed, and particularly m_{1,1}^{v2c}, m_{1,2}^{v2c} and m_{1,3}^{v2c} output to the check nodes c₁ 311, c₂ 313 and c₃ 315 through an edge, may be expressed as Equation 5 below:

m_{1,1}^{v2c}=y₁+m_{1,1}^{c2v}+m_{2,1}^{c2v}+m_{3,1}^{c2v}−m_{1,1}^{c2v}=y₁+m_{2,1}^{c2v}+m_{3,1}^{c2v}

m_{1,2}^{v2c}=y₁+m_{1,1}^{c2v}+m_{2,1}^{c2v}+m_{3,1}^{c2v}−m_{2,1}^{c2v}=y₁+m_{1,1}^{c2v}+m_{3,1}^{c2v}. [Eqn 5]

m_{1,3}^{v2c}=y₁+m_{1,1}^{c2v}+m_{2,1}^{c2v}+m_{3,1}^{c2v}−m_{3,1}^{c2v}=y₁+m_{1,1}^{c2v}+m_{2,1}^{c2v}

The output message m_{j,i}^{c2v} of a check node, expressed in Equation 2, will now be described with reference to FIG. 4. Since the input messages 400 of the check node c₁ 401 include m_{1,1}^{v2c}, m_{2,1}^{v2c} and m_{3,1}^{v2c} input from variable nodes v₁ 411, v₂ 413 and v₃ 415, as shown in FIG. 4, the messages 450 output after an update has been performed, that is, m_{1,1}^{c2v}, m_{1,2}^{c2v} and m_{1,3}^{c2v} output to the variable nodes v₁ 411, v₂ 413 and v₃ 415 through an edge, may be expressed as Equation 6 below:

m_{1,1}^{c2v}=F⁻¹(F(m_{1,1}^{v2c})+F(m_{2,1}^{v2c})+F(m_{3,1}^{v2c})−F(m_{1,1}^{v2c}))=F⁻¹(F(m_{2,1}^{v2c})+F(m_{3,1}^{v2c}))

m_{1,2}^{c2v}=F⁻¹(F(m_{1,1}^{v2c})+F(m_{2,1}^{v2c})+F(m_{3,1}^{v2c})−F(m_{2,1}^{v2c}))=F⁻¹(F(m_{1,1}^{v2c})+F(m_{3,1}^{v2c}))

m_{1,3}^{c2v}=F⁻¹(F(m_{1,1}^{v2c})+F(m_{2,1}^{v2c})+F(m_{3,1}^{v2c})−F(m_{3,1}^{v2c}))=F⁻¹(F(m_{1,1}^{v2c})+F(m_{2,1}^{v2c})) [Eqn. 6]

As described above, the decoder for the LDPC code decodes information bits through message passing in the bipartite graph, that is, in the iterative calculation scheme through exchange of messages, i.e., m_{i,j}^{v2c} and m_{j,i}^{c2v}, between variable nodes and check nodes, as described with reference to FIGS. 3 and 4. Here, the iterative calculation scheme is a scheme of updating messages of all variable nodes, i.e., outputting m_{i,j}^{v2c}, and then of updating messages of all check nodes, i.e., outputting m_{j,i}^{c2v}, and corresponds to a flooding scheduling scheme. That is, according to the flooding scheduling scheme, a decoder for the LDPC code is designed in a fully-parallel structure, so that messages are updated at every cycle.

However, the decoder having the fully-parallel structure has a problem in that the interconnection complexity of edges existing between nodes increases. In addition, memories for storing each edge message, in which the memories include a memory for storing an edge message, i.e., m_{i,j}^{v2c}, transmitted from a variable node to a check node, and a memory for storing an edge message, i.e., m_{j,i}^{c2v}, transmitted from a check node to a variable node.

FIG. 5 is a block diagram schematically illustrating the configuration of a decoder for the LDPC code.

The decoder includes edge memories for storing edge messages, i.e., a C2V edge message memory 501 for storing an m_{j,i}^{c2v} and a V2C edge message memory 503 for storing an m_{i,j}^{v2c}, a check node processor 505 and a variable node processor 507 for processing update operations of a check node and a variable node, respectively, switching modules 509 and 511 for rotating messages existing between the node processors 505 and 507 and the message memories 501 and 503, a decoder control module 515, and a message ordering module 517.

The decoder control module 515 of the decoder generates an index of an edge memory and an index of a degree memory 513 for storing degree information of variable nodes and check nodes, increases the value of each index at every cycle, generates read addresses of the message memories 501 and 503 corresponding to the edge memory index, and generates a variable node degree and a check node degree corresponding to the index of the degree memory 513. In addition, when the decoder reads a message (i.e., m_{j,i}^{c2v}) of the C2V edge message memory 501 and a y₁ which is an LLR of an input buffer 519, the variable node processor 507 performs an update operation to generate and store an m_{i,j}^{v2c} in the V2C edge message memory 503. Also, when the decoder reads a message (i.e., m_{i,j}^{v2c}) of the V2C edge message memory 503, the check node processor 505 performs an update operation to generate and store an m_{j,i}^{c2v} in the C2V edge message memory 501.

As described above, the decoder includes two edge message memories 501 and 503 and two node processors 505 and 507.

FIG. 6 is a block diagram schematically illustrating the configuration of a node processor in the decoder.

The node processor serially receives messages read from each edge message memory, and processes a message input through an edge corresponding to a degree of a node, and particularly to a degree of a variable node. That is, the node processor processes a message corresponding to the edge degree of a node. For example, when three edges are generated from one node, the node processor receives the messages during three cycles, stores the summation value of the three received messages and the three received messages in a first-in first-out (FIFO) module, and generates output messages one by one through subtraction between a summation value during the next three cycles and the input value of the FIFO module.

Meanwhile, the decoder which decodes an LDPC code through the flooding scheduling scheme and the message-passing algorithm, that is, the receiver which receives data by decoding information bits through the iterative calculation scheme has a problem in that a data decoding performance, i.e., a data reception performance, is poor because the convergence speed of the LLR is slow. In other words, since the receiver of decoding an LDPC code by means of the iterative calculation scheme and receiving data necessitates many iterative calculations in order to obtain high-reliability decoding bits, the data decoding speed becomes slow, so that the data reception rate, i.e., the data processing speed, becomes slow, thereby making the data reception performance deteriorate.

Also, as described above, messages input through edges corresponding to degrees of each node are processed by each node processor during variable operation cycles. In this case, as the degrees of a variable node and the degrees of a check node are different, for example, as the degrees of a variable node have values of 3 to 4 and the degrees of a check node have values of 6 to 22, memories for storing information about the degrees of each node are required, thereby increasing the system complexity. Furthermore, since the decoder includes two memories, i.e., a V2C edge message memory and a C2V edge message memory, for storing edge messages, the system complexity increases. Particularly, as the number of elements having a value other than “0” in the “H” matrix increases, a required memory size increases, thereby further increasing the system complexity.

### SUMMARY OF THE INVENTION

To address the above-discussed deficiencies of the prior art, it is a primary object to provide a method and apparatus for receiving data in a communication system.

Also, the present invention provides a method and apparatus for receiving data in a communication system using an LDPC code.

Also, the present invention provides a method and apparatus for decoding an LDPC code and receiving data in a communication system using the LDPC code.

In addition, the present invention provides a method and apparatus capable of reducing the system complexity and improving the data reception performance in a communication system using an LDPC code.

In accordance with an aspect of the present invention, there is provided an apparatus for receiving data in a communication system, the apparatus including a first memory for receiving data and storing input messages of respective check nodes in a low-density parity check (LDPC) matrix of the received data; a second memory for storing a first summation value of all the input messages of the check nodes; and a decoder for subtracting the input messages of the respective check nodes from the first summation value, and updating input messages of respective variable nodes corresponding to the check nodes.

In accordance with another aspect of the present invention, there is provided a method for receiving data in a communication system, the method including the steps of receiving data and storing input messages of respective check nodes in a low-density parity check (LDPC) matrix of the received data; adding up all of the input messages of the check nodes and storing a calculated first summation value; and updating input messages of variable nodes corresponding to the respective check nodes, with values obtained by subtracting the input messages of the respective check nodes from the first summation value.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a parity check matrix of a general LDPC code;

FIG. 2 is a view illustrating a bipartite graph of the LDPC code shown in FIG. 1;

FIG. 3 is a view explaining input and output messages of a variable node in the bipartite graph of the LDPC code;

FIG. 4 is a view explaining input and output messages of a check node in the bipartite graph of the LDPC code;

FIG. 5 is a block diagram schematically illustrating the configuration of a decoder for the LDPC code;

FIG. 6 is a block diagram schematically illustrating the configuration of a node processor in the decoder;

FIG. 7 is a view explaining input and output messages of a check node in a bipartite graph of an LDPC code in a communication system according to an exemplary embodiment of the present invention;

FIG. 8 is a view explaining a message-passing operation of a receiver in a communication system according to an exemplary embodiment of the present invention;

FIG. 9 is a block diagram schematically illustrating the configuration of a receiver in a communication system according to an exemplary embodiment of the present invention;

FIG. 10 is a block diagram schematically illustrating the configuration of the adaptive variable processor of the decoder in the communication system according to an exemplary embodiment of the present invention;

FIG. 11 is a view explaining the operation of the adaptive variable processor of the decoder in a communication system according to an exemplary embodiment of the present invention;

FIG. 12 is view explaining the operation of the adaptive variable processor, shown in FIG. 11;

FIG. 13 is a view illustrating a parity check matrix of an LDPC code in a communication system according to an exemplary embodiment of the present invention; and

FIG. 14 is a flowchart illustrating the address ordering operation of the decoder in the communication system according to an exemplary embodiment of the present invention.

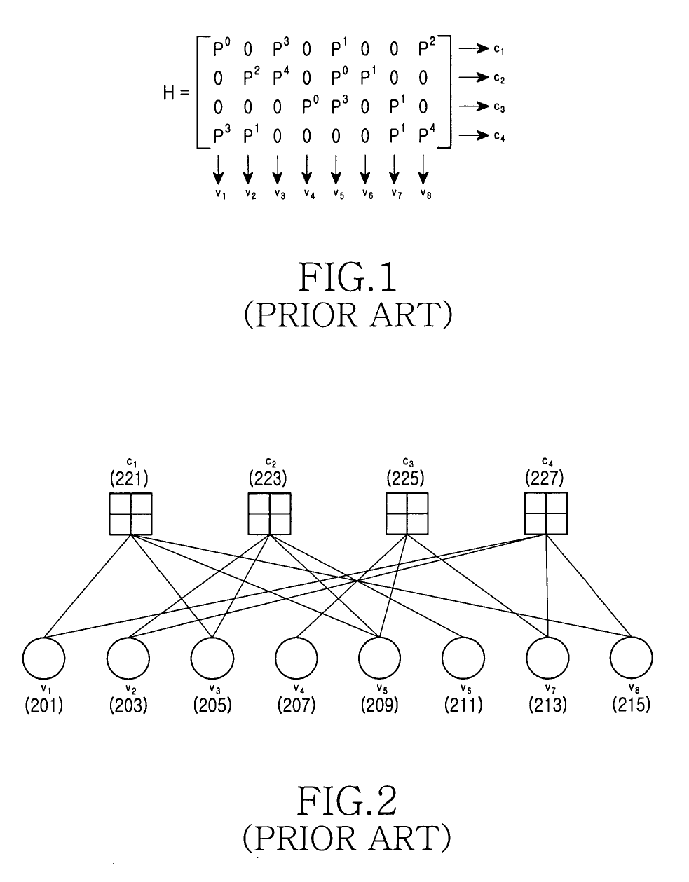

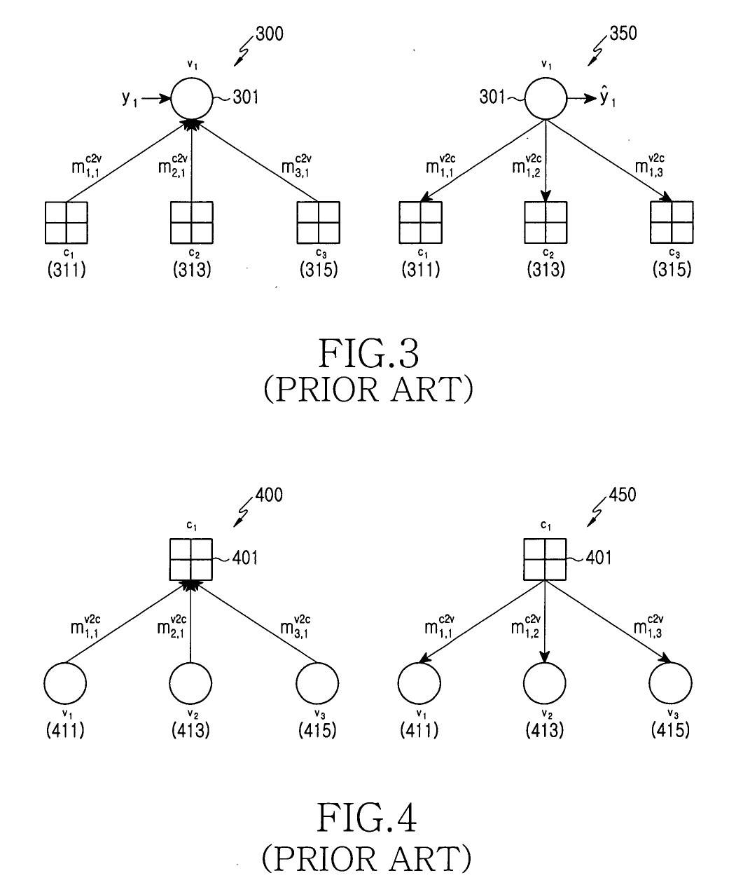

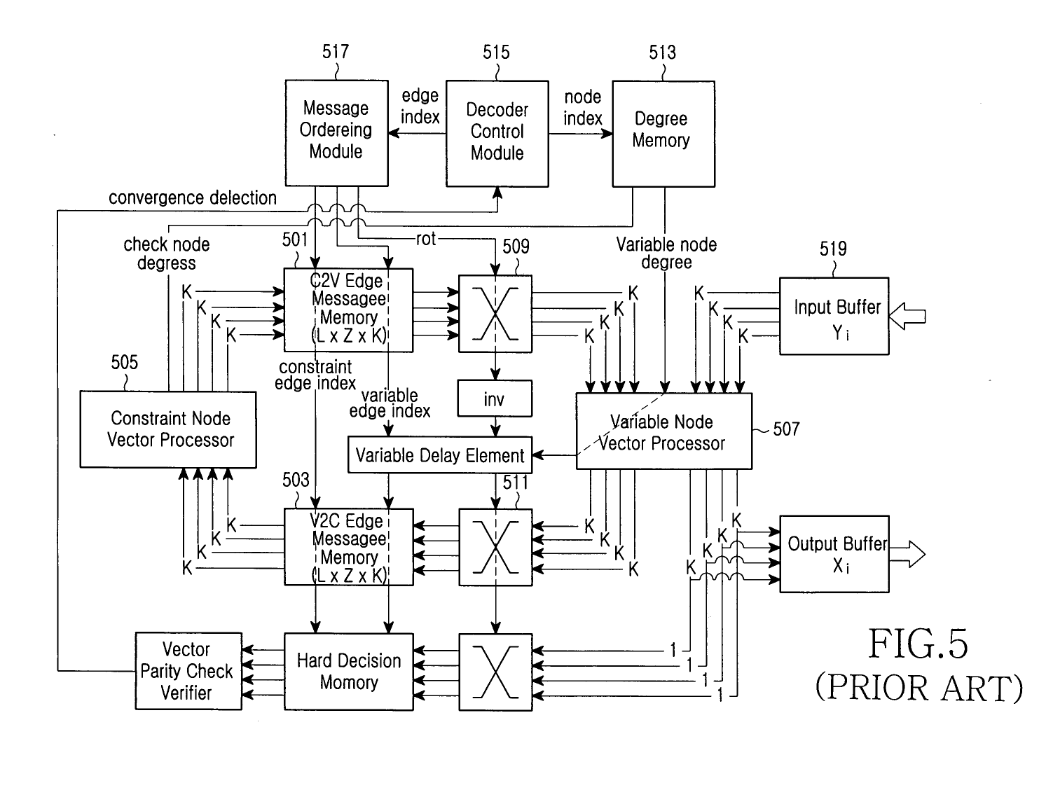

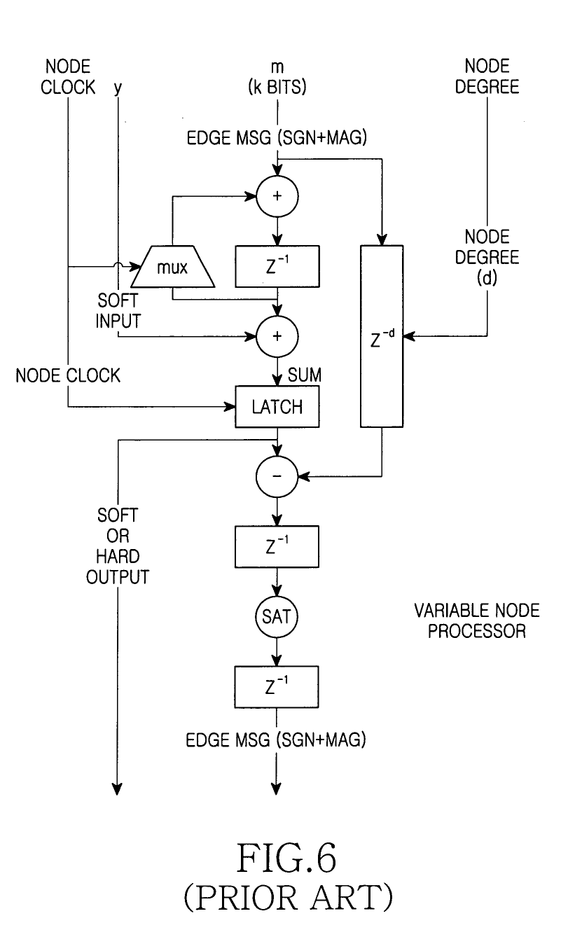

### DETAILED DESCRIPTION OF THE INVENTION

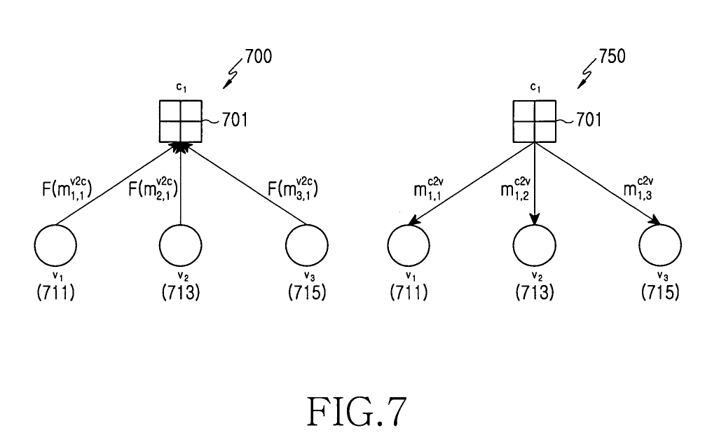

FIGS. 7 through 14, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless communication systems.

The present invention proposes a method and apparatus for receiving data in a communication system using a low-density parity check (LDPC) code. Although the following description will be given about a communication system using an LDPC code as an example, it should be noted that the data receiving method and apparatus according to the present invention can be applied to different communication systems.

Also, the present invention proposes a method and apparatus for receiving data which can improve the data processing speed of a receiver in a communication system using an LDPC code. Also, the present invention proposes a method and apparatus for implementing a receiver which decodes data through a message-passing operation using a variable node-based serial scheduling scheme and receives the data in a communication system according to an exemplary embodiment of the present invention.

In addition, the present invention provides a method and apparatus for receiving data, which can reduce the complexity of a receiver in a communication system using an LDPC code. Also, the present invention proposes a method and apparatus for receiving data which reduces the memory capacity required for storing messages, that is, a message (V2C message) transmitted from a variable node to a check node and a message (C2V message) transmitted from a check node to a variable node, which are transmitted through edges generated between variable nodes and check nodes corresponding to elements in a parity check matrix of an LDPC code, thereby reducing the complexity of the receiver.

According to an exemplary embodiment of the present invention, all of the two types of messages are not stored, and only one type of message, e.g., only a V2C message, is stored. Then, data is decoded in such a manner as to calculate a different message, e.g., a C2V message, using the stored V2C message and a check node message, e.g., a memory value set in a check node, thereby reducing the complexity of the receiver. That is, according to an exemplary embodiment of the present invention, which will be described later, a memory value of an edge memory storing a V2C message and a summation value of a check node through a summation function are used to calculate a C2V message, so that a decoder can be implemented with one edge memory, thereby reducing the complexity of the receiver.

First, variables to be used in an embodiment of the present invention, described later, are defined as follows:

yᵢ represents an a priori log likelihood ratio (LLR) corresponding to an i^{th} variable node (i^{th} reception bit);

ŷᵢ represents a bit value decoded in an i^{th} variable node;

C(i) represents an index set of variable nodes connected to an i^{th} variable node;

C(j) represents an index set of check nodes connected to a j^{th} check node;

m_{i,j}^{v2c} represents an edge message transmitted from an i^{th} variable node to a j^{th} check node;

m_{j,i}^{c2v} represents an edge message transmitted from a j^{th} check node to an i^{th} variable node;

$$F ( x ) \text{:} log \frac{1 + {e}^{- x}}{1 - {e}^{- x}} ;$$

$${F}^{- 1} ( x ) \text{:} {( log \frac{1 + {e}^{- x}}{1 - {e}^{- x}} )}^{- 1} ; and$$

Pᵢ^{llr} represents an a posteriori LLR of an i^{th} variable node.

FIG. 7 is a view explaining input and output messages of a check node in a bipartite graph of an LDPC code in a communication system according to an exemplary embodiment of the present invention.

FIG. 7 illustrates the input and output messages of check node c₁ when an edge is generated between one of multiple check nodes, i.e., the check node c₁ and three variable nodes v₁, v₂ and v₃.

The input messages 700 of the check node c₁ 701 include edge messages F(m_{1,1}^{v2c}), F(m_{2,1}^{v2c}) and F(m_{3,1}^{v2c}) input from variable nodes v₁ 711, v₂ 713 and v₃ 715 through an edge. When the messages F(m_{1,1}^{v2c}), F(m_{2,1}^{v2c}) and F(m_{3,1}^{v2c}) are input from the variable nodes v₁ 711, v₂ 713 and v₃ 715 to the check node c₁ 701, as described above, and a summation value “SUM_F=F(m_{1,1}^{v2c})+F(m_{2,1}^{v2c})+F(m_{3,1}^{v2c})” of the check node c₁ 701 obtained through the summation function is stored, the check node c₁ 701 outputs output messages through the message-passing operation. That is, the output messages 750 of the check node c₁ 701 include edge messages m_{1,1}^{c2v}, m_{1,2}^{c2v}, m_{1,3}^{c2v} transmitted to the variable nodes v₁ 711, v₂ 713 and v₃ 715 through an edge. Here, the output messages 750, that is, m_{1,1}^{c2v}, m_{1,2}^{c2v}, m_{1,3}^{c2v}, of the check node c₁ 701 may be expressed as Equation 7 below:

m_{1,1}^{c2v}=F⁻¹(SUM_{—}F−F(m_{1,1}^{v2c}))

m_{1,2}^{c2v}=F⁻¹(SUM_{—}F−F(m_{2,1}^{v2c})). [Eqn. 7]

m_{1,3}^{c2v}=F⁻¹(SUM_{—}F−F(m_{3,1}^{v2c}))

In the communication system according to an exemplary embodiment of the present invention, the receiver stores one edge message, for example, V2C message m_{i,j}^{v2c}, which is an edge message transmitted from a variable node to a check node, and decodes information bits through the message-passing operation using the stored edge message and a summation value SUM_F of one node, e.g., a check node. The following description will be given about information bit decoding through a message-passing operation of the receiver in the communication system according to an exemplary embodiment of the present invention.

First, with respect to all variable nodes and check nodes in the bipartite graph of the LDPC code in the communication system according to an exemplary embodiment of the present invention, message m_{vc}^{v2c} input from a variable node to a check node, and Q_{c}, which is a summation value SUM_F of a check node, are initialized as expressed in Equation 8 below:

$${m}_{vc}^{v 2 c} = F ( {y}_{v} ) \\ {Q}_{c} = {\sum }_{v ∈ V ( c )} F ( {y}_{v} ) . \qquad [ Eqn . 8 ]$$

Then, with respect to all variable nodes and check nodes, a check node message is updated through the iterative calculation between the check nodes and the variable nodes using the message m_{vc}^{v2c} input from a variable node to a check node and Q_{c}, which is a summation value SUM_F of a check node, as expressed in Equation 9 below:

$${q}_{cv}^{tmp} = {Q}_{c} - {m}_{vc}^{v 2 c} \\ {m}_{cv} = {F}^{- 1} ( {q}_{vc}^{tmp} ) \\ {new\_m}_{vc}^{v 2 c} = {y}_{v} + ( {\sum }_{{c}^{′} ∈ N ( v )} {m}_{{c}^{′} v} - {m}_{cv} ) . \\ {t}_{cv}^{tmp} = F ( {new\_m}_{vc}^{v 2 c} ) \\ {m}_{vc}^{v 2 c} = {t}_{cv}^{tmp} \\ {Q}_{c} = {q}_{cv}^{tmp} + {t}_{cv}^{tmp} \qquad [ Eqn . 9 ]$$

In Equation 9, q_{cv}^{tmp} is a difference between initial Q_{c} and m_{vc}^{v2c}, expressed in Equation 8, and represents a summation value of a temporary check node, m_{cv} represents a C2V message, m_{c,v} represents a C2V message transmitted from a check node, other than the check node which transmits the m_{cv}, new_m_{vc}^{v2c} represents a V2C message after an update of a variable node, and t_{cv}^{tmp} represents a temporary check node value.

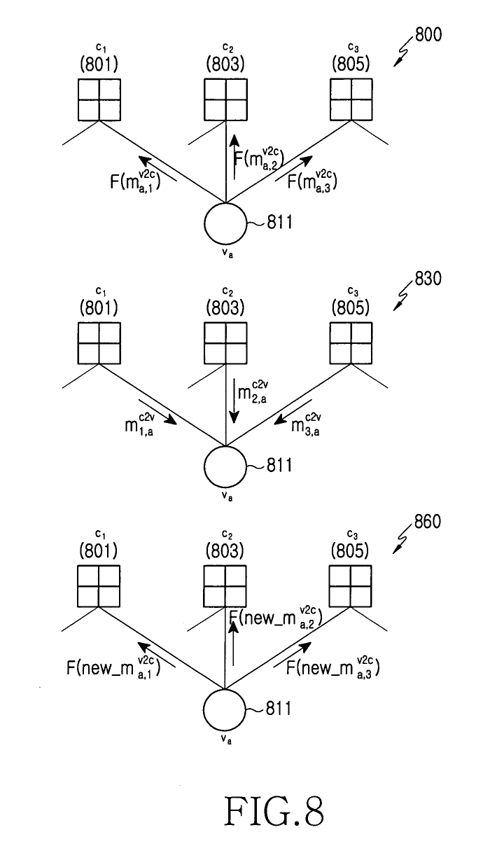

FIG. 8 is a view explaining a message-passing operation of a receiver in a communication system according to an exemplary embodiment of the present invention. FIG. 8 shows an update through a message-passing operation between one variable node Vₐ and three check nodes c₁, c₂ and c₃ when edges are generated between the variable node Vₐ and the three check nodes c₁, c₂ and c₃ among multiple check nodes.

When edge messages F(mₐ₁^{v2c}), F(mₐ₂^{v2c}) and F(mₐ₃^{v2c}) are input from variable node Vₐ 811 to check nodes, that is, to c₁ 801, c₂ 803 and c₃ 805 (see reference numeral 800), summation values of temporary check nodes are generated by using the message values mₐ₁^{v2c}, mₐ₂^{v2c} and mₐ₃^{v2c} of the input messages F(mₐ₁^{v2c}), F(mₐ₂^{v2c}) and F(mₐ₃^{v2c}), and Q₁, Q₂ and Q₃, which are the summation values SUM_F of the check nodes c₁ 801, c₂ 803 and c₃ 805, as expressed in Equation 10 below:

q₁ₐ^{tmp}=Q₁−mₐ₁^{v2c}

q₂ₐ^{tmp}=Q₂−mₐ₂^{v2c}. [Eqn. 10]

q₃ₐ^{tmp}=Q₃−mₐ₃^{v2c}

Then, the check nodes c₁ 801, c₂ 803 and c₃ 805 perform update operations, that is, the check nodes generate messages m_{cv}, i.e., m₁ₐ^{c2v}, m₂ₐ^{c2v} and m₃ₐ^{c2v} from the q₁ₐ^{tmp}, q₂ₐ^{tmp} and q₃ₐ^{tmp} of Equation 10 through pre-defined function F⁻¹(x), as expressed in Equation 11 below, and output the generated m₁ₐ^{c2v}, m₂ₐ^{c2v} and m₃ₐ^{c2v} to the variable node Vₐ 811 (see reference numeral 830):

m₁ₐ^{c2v}=F⁻¹(q₁ₐ^{tmp})

m₂ₐ^{c2v}=F⁻¹(q₂ₐ^{tmp}). [Eqn. 11]

m₃ₐ^{c2v}=F⁻¹(q₃ₐ^{tmp})

When receiving edge messages m₁ₐ^{c2v}, m₂ₐ^{c2v} and m₃ₐ^{c2v} from the check nodes c₁ 801, c₂ 803 and c₃ 805, the variable node Vₐ 811 performs an update operation, that is, the variable node Vₐ 811 generates messages new_mₐ₁^{v2c}, new_mₐ₂^{v2c} and new_mₐ₃^{v2c}, as expressed in Equation 12 below, and outputs the messages new_mₐ₁^{v2c}, new_mₐ₂^{v2c} and new_mₐ₃^{v2c} to the check nodes c₁ 801, c₂ 803 and c₃ 805, respectively (see reference numeral 860):

$${new\_m}_{a 1}^{v 2 c} = {y}_{a} + {\sum }_{{c}^{′} ∈ N ( a )} {m}_{{c}^{′} v}^{c 2 v} - {m}_{1 a}^{c 2 v} \\ {new\_m}_{a 2}^{v 2 c} = {y}_{a} + {\sum }_{{c}^{′} ∈ N ( a )} {m}_{{c}^{′} v}^{c 2 v} - {m}_{2 a}^{c 2 v} \\ {new\_m}_{a 3}^{v 2 c} = {y}_{a} + {\sum }_{{c}^{′} ∈ N ( a )} {m}_{{c}^{′} v}^{c 2 v} - {m}_{3 a}^{c 2 v} . \qquad [ Eqn . 12 ]$$

Accordingly, in the communication system according to an exemplary embodiment of the present invention, the receiver updates the summation values Q_{c}, i.e., Q₁, Q₂ and Q₃ among the check nodes, and the V2C messages m^{v2c}, i.e., mₐ₁^{v2c}, mₐ₂^{v2c} and m mₐ₃^{v2c}, as expressed in Equation 13 below:

mₐ₁^{v2c}=t₁ₐ^{tmp}=F(new_{—}mₐ₁^{v2c})

mₐ₂^{v2c}=t₂ₐ^{tmp}=F(new_{—}mₐ₂^{v2c})

mₐ₃^{v2c}=t₃ₐ^{tmp}=F(new_{—}mₐ₃^{v2c}). [Eqn. 13]

Q₁=q₁ₐ^{tmp}+t₁ₐ^{tmp}

Q₂=q₂ₐ^{tmp}+t₂ₐ^{tmp}

Q₃=q₃ₐ^{tmp}+t₃ₐ^{tmp}

As described with reference to FIG. 8, the receiver in the communication system according to an exemplary embodiment of the present invention receives data by decoding information bits through the message-passing operation using the iterative calculation between check nodes and variable nodes. In this case, since the receiver decodes the messages of the variable nodes and check nodes at the same time through the latest updated values, the convergence speed of the LLR is fast, thereby improving the data decoding performance, that is, the data receiving and processing performance. In addition, the receiver includes only one memory for storing an edge message, e.g., a V2C message, and only one node memory, e.g., a check node memory for storing summation values of check nodes, thereby reducing the complexity of the receiver.

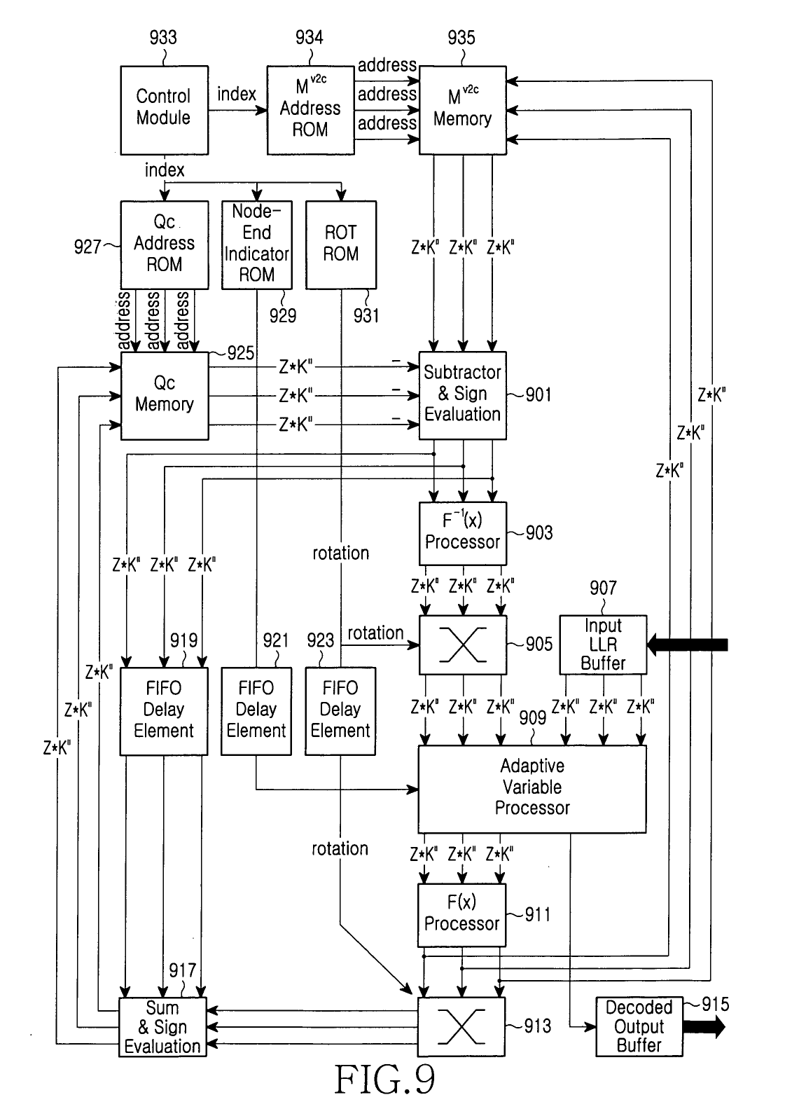

FIG. 9 is a block diagram illustrating the configuration of a decoder for decoding an LDPC code in a receiver of a communication system according to an exemplary embodiment of the present invention.

The decoder includes an edge message memory 935 for storing the value of an edge message, i.e., F(m_{vc}^{v2c}), transmitted from a variable node to a check node, a Q_{c} memory 925 for storing a summation value of a check node, a subtractor 901 for performing a subtraction operation between values stored in the edge message memory 935 and Q_{c} memory 925 in order to calculate a C2V message, a first function processor 903 for calculating the function F⁻¹(x) with a value obtained by the subtraction operation of the subtractor 901, a second function processor 911 for calculating the function F(x) so as to store a V2C message in the Q_{c} memory 925, an adaptive variable processor 909 for performing an update operation according to the degree of a node, switching modules 905 and 913 connected to the processors 903, 909 and 913 so as to enable messages to be rotated, a message address memory 934 for storing information about message address ordering of the edge message memory 935, a Q_{c} address memory 927 for storing information about message address ordering of the Q_{c} memory 925, an indicator memory 929 for indicating the last message in each variable node by means of a value of “1” or “0,” a rotation storage module 931 for storing a rotation number of each switching module 905 and 913, a control module 933 for controlling the decoder of the LDPC code, delay modules 919, 921 and 923, buffers 907 and 915, and a sum & sign evaluator 917.

The control module 933 in the decoder reads values stored in the edge message memory 935 and Q_{c} memory 925 according to each corresponding address, while increasing, by one at every cycle, the indexes of the message address memory 934 and Q_{c} address memory 927, which store information about message addresses and Q_{c} addresses. Then, the subtractor 901 performs a subtraction operation on the values read from the edge message memory 935 and Q_{c} memory 925, and the first function processor 903 takes the function F⁻¹(x) of a value obtained by the subtraction operation, thereby calculating a C2V message.

The adaptive variable processor 909 performs an update operation on the C2V message calculated as above and an a priori LLR according to an indicator stored in the indicator memory 929, thereby generating a V2C message and a decoded information bit. The decoded information bit is stored in the buffer 915, and a final information bit is output when the decoding operation has been completed. The indicator memory 929 indicates that a current message is the last message in a node by means of a value of “1” or “0,” as described above. For example, the value of “1” may indicate that a current message is the last message, while the value of “0” indicates that the current message is not the last message. In this case, the decoder can identify a progressing state of messages through an indicator, i.e., a value of “1” or “0,” in the indicator memory 929, so that it is possible to reduce the complexity of the receiver, as compared with a receiver including the conventional decoder where the progressing state of messages is identified through the degree of each node.

Next, the second function processor 911 in the decoder takes the function F(x) of the V2C message output from the adaptive variable processor 909, and stores a result of the calculation in the edge message memory 935. Also, the decoder adds up a value obtained by taking the function F(x) of the V2C message and a value obtained by subtracting a previous C2V message value from a total summation value in a previous stage, and stores the resultant summation value in the Q_{c} memory 925. In this case, the summation value of the check nodes is updated through an initially-set summation value, a new C2V message is calculated, and a summation value obtained by taking the function F(x) of the calculated new C2V message is stored in the Q_{c} memory 925. As a result, when an edge message of a check node is processed, an updated edge message is processed, so that the LLR convergence speed becomes faster than that of a flooding scheduling scheme, thereby improving a decoding performance, that is, a data processing performance.

In other words, while a decoder based on the flooding scheduling scheme uses only “Z” as parallel factors in order to improve the decoding performance thereof, the decoder of the receiver in the communication system according to an exemplary embodiment of the present invention includes memory banks as many as the size of “Z,” which are connected in parallel with each other, as well as the “Z,” as parallel factors, thereby processing Z vectors as many as the number of memory banks at one time. For example, when three edges are generated from one variable node, the decoder based on the flooding scheduling scheme completes the message processing through update, i.e., through update during six cycles as time “t” goes by, as shown in Table 1, but the decoder according to an exemplary embodiment of the present invention completes the message processing through update during only one cycle, as shown in Table 2.

TABLE 1

| Time | Operation |
|---|---|
| t = 0 | y₁ + m₁₁^{v2c} |
| t = 1 | y₁ + m₁₁^{v2c} + m₂₁^{v2c} |
| t = 2 | y₁ + m₁₁^{v2c} + m₂₁^{v2c} + m₃₁^{v2c} |
| t = 3 | y₁ + m₁₁^{v2c} + m₂₁^{v2c} + m₃₁^{v2c} − m₁₁^{v2c} |
| t = 4 | y₁ + m₁₁^{v2c} + m₂₁^{v2c} + m₃₁^{v2c} − m₂₁^{v2c} |
| t = 5 | y₁ + m₁₁^{v2c} + m₂₁^{v2c} + m₃₁^{v2c} − m₃₁^{v2c} |

TABLE 2

| Time | Operation |
|---|---|
| t = 0 | m₁₁^{v2c} = y₁ + m₁₁^{v2c} + m₂₁^{v2c} + m₃₁^{v2c} − m₁₁^{v2c} |
| | m₁₂^{v2c} = y₁ + m₁₁^{v2c} + m₂₁^{v2c} + m₃₁^{v2c} − m₁₂^{v2c} |
| | m₁₃^{v2c} = y₁ + m₁₁^{v2c} + m₂₁^{v2c} + m₃₁^{v2c} − m₁₃^{v2c} |

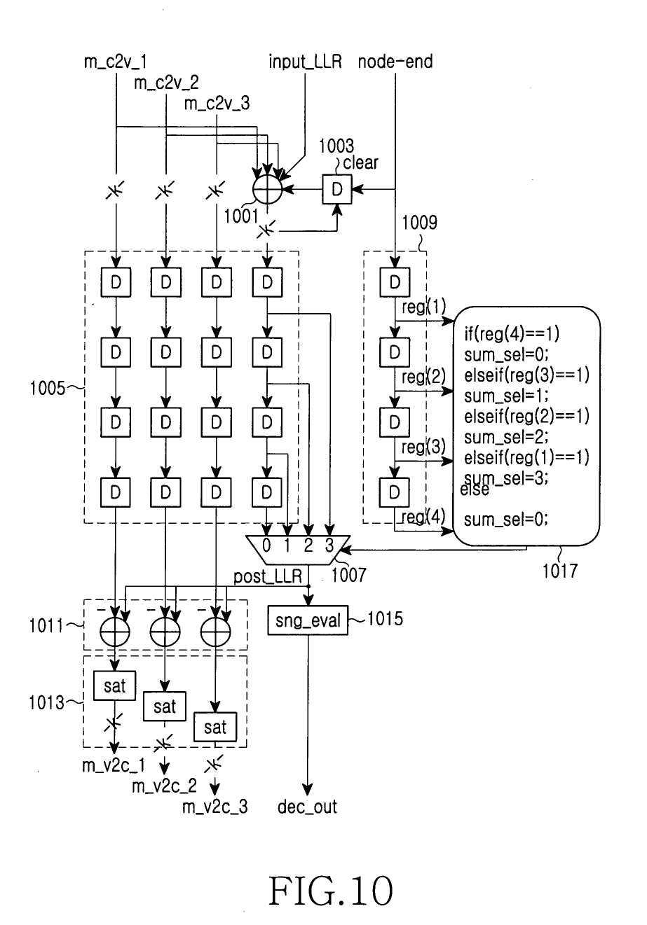

FIG. 10 is a block diagram schematically illustrating the configuration of the adaptive variable processor of the decoder in the communication system according to an exemplary embodiment of the present invention.

FIG. 10 illustrates the configuration of the adaptive variable processor which processes a maximum of three input messages (e.g., C2V messages) and outputs output messages (e.g. V2C messages) and a decoded information bit.

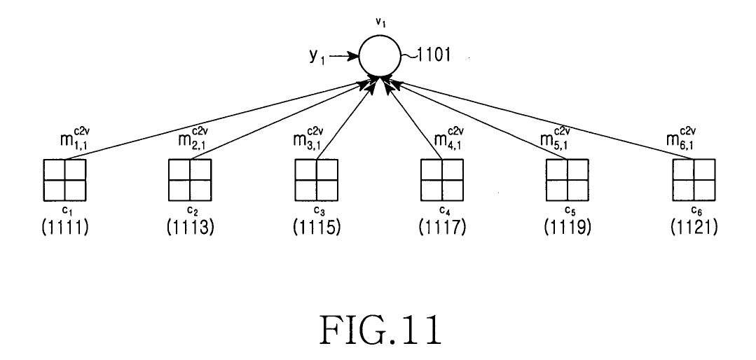

The adaptive variable processor includes an accumulator 1001 for storing input messages (i.e. three C2V messages) and yᵢ, which is an a priori LLR, a first first-in-first-out (FIFO) module 1003 for transmitting a clear signal to reset the accumulator 1001 to the accumulator 1001 according to a variable node message indication signal “node-end” transmitted from the indicator memory 929 of FIG. 9, a second FIFO module 1005 for transmitting the input messages and the output of the accumulator 1001 to a subtraction module 1011 and a multiplexer 1007, a third FIFO module 1009 for transmitting the indication signal to a control module 1017, the control module 1017 for outputting a selection signal for the multiplexer 1007 according to the indication signal, the multiplexer 1007 for outputting an a posteriori LLR according to the selection signal, the subtraction module 1011 for performing a subtraction operation between the a posteriori LLR and messages transmitted through the second FIFO module 1005, i.e., subtracting the respective messages from a sum of all messages, a saturation module 1013 for saturating the output message value of the subtraction module 1011 and outputting V2C messages to the second function processor 911 of FIG. 9, and a sign-evaluation module 1015 for identifying the a posteriori LLR output from the multiplexer 1007 and outputting a decoded information bit to the output buffer 915 of FIG. 9. Hereinafter, the operation of the adaptive variable processor will be described in more detail with reference to FIG. 11.

FIG. 11 is a view explaining the operation of the adaptive variable processor of the decoder in a communication system according to an exemplary embodiment of the present invention. FIG. 11 illustrates a bipartite graph of the LDPC code where edges are generated between variable node v₁ among multiple variable nodes and six check nodes c₁, c₂, c₃, c₄, c₅ and c₆ in order to explain the operation of the adaptive variable processor in the decoder of the LDPC code according to an exemplary embodiment of the present invention.

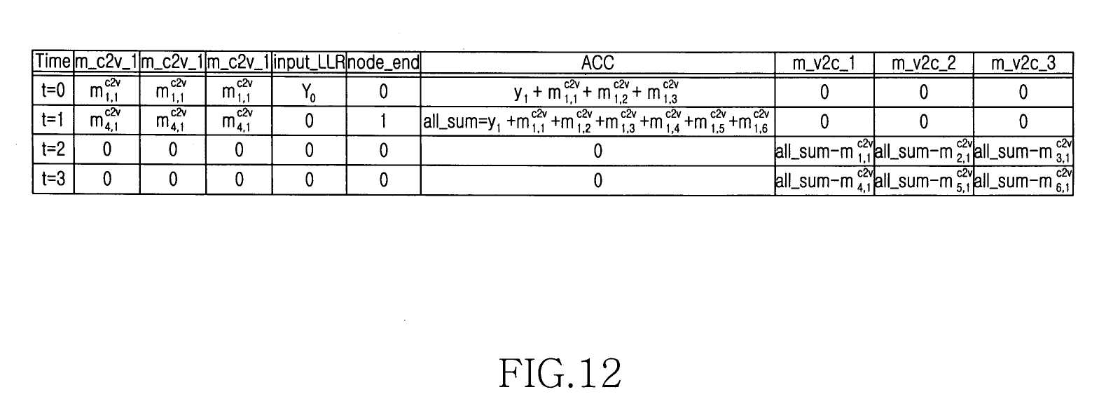

To the adaptive variable processor, messages m_{1,1}^{c2v}, m_{2,1}^{c2v}, m_{3,1}^{c2v}, m_{4,1}^{c2v}, m_{5,1}^{c2v} and m_{6,1}^{c2v} transmitted from the check nodes c₁ 1111, c₂ 1113, c₃ 1115, c₄ 1117, c₅ 1119 and c₆ 1121 are input as input messages of the variable node v₁ 1101, and an a priori LLR “y₁” is input as an input LLR. In this case, since the adaptive variable processor has three message input terminals, and the messages m_{1,1}^{c2v}, m_{2,1}^{c2v}, m_{3,1}^{c2v}, m_{4,1}^{c2v}, m_{5,1}^{c2v} and m_{6,1}^{c2v} transmitted from the check nodes c₁ 1111, c₂ 1113, c₃ 1115, c₄ 1117, c₅ 1119 and c₆ 1121 are six in number, the adaptive variable processor divides the messages m_{1,1}^{c2v}, m_{2,1}^{c2v}, m_{3,1}^{c2v}, m_{4,1}^{c2v}, m_{5,1}^{c2v} and m_{6,1}^{c2v} into two groups, that is, into a first group containing the messages m_{1,1}^{c2v}, m_{2,1}^{c2v} and m_{3,1}^{c2v} and a second group containing the messages m_{4,1}^{c2v}, m_{5,1}^{c2v} and m_{6,1}^{c2v}. Next, the messages m_{1,1}^{c2v}, m_{2,1}^{c2v} and m_{3,1}^{c2v} contained in the first group are input to the adaptive variable processor, and then the messages m_{4,1}^{c2v}, m_{5,1}^{c2v} and m_{6,1}^{c2v} contained in the second group are input to the adaptive variable processor. In this case, when the messages contained in the first group are input to the adaptive variable processor, a variable node message indication signal transmitted from the indicator memory 929 of FIG. 9 includes the value of “0” to indicate that the current message is not the last message. Then, when the messages contained in the second group are input to the adaptive variable processor, the indication signal includes the value of “1” to indicate that the current message is the last message. When the input messages m_{1,1}^{c2v}, m_{2,1}^{c2v}, m_{3,1}^{c2v}, m_{4,1}^{c2v}, m_{5,1}^{c2v} and m_{6,1}^{c2v} are divided into two groups and are input to the adaptive variable processor, an update operation is performed as time “t” goes by, as shown in FIG. 12.

FIG. 12 is view explaining the operation of the adaptive variable processor in relation to FIG. 11.

When t=0, the messages m_{1,1}^{c2v}, m_{2,1}^{c2v} and m_{3,1}^{c2v} contained in the first group are input, and the input messages m_{1,1}^{c2v}, m_{2,1}^{c2v} and m_{3,1}^{c2v} are accumulated and stored in a register of the accumulator 1001. Then, when t=1, the messages m_{4,1}^{c2v}, m_{5,1}^{c2v} and m_{6,1}^{c2v} contained in the second group are input, and the accumulator 1001 calculates a summation value of all the messages m_{1,1}^{c2v}, m_{2,1}^{c2v}, m_{3,1}^{c2v}, m_{4,1}^{c2v}, m_{5,1}^{c2v} and m_{6,1}^{c2v} contained in the first and second groups. Thereafter, when t=2, the adaptive variable processor subtracts each of messages m_{1,1}^{c2v}, m_{2,1}^{c2v} and m_{3,1}^{c2v} of the first group from the summation value in accordance with the indication signal having the value of “0,” thereby outputting V2C messages corresponding to the messages m_{1,1}^{c2v}, m_{2,1}^{c2v} and m_{3,1}^{c2v}, and a decoded information bit. Next, when t=3, the adaptive variable processor subtracts each of the messages m_{4,1}^{c2v}, m_{5,1}^{c2v} and m_{6,1}^{c2v} of the second group from the summation value in accordance with the indication signal having the value of “1,” thereby outputting V2C messages corresponding to the messages m_{4,1}^{c2v}, m_{5,1}^{c2v} and m_{6,1}^{c2v}, and a decoded information bit. As described above, the adaptive variable processor decodes (i.e., processes) data not according to the degrees of nodes, but according to the indication signal, thereby significantly increasing the data processing speed.

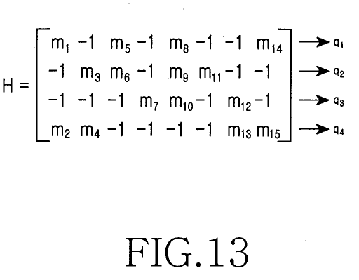

FIG. 13 is a view showing an example of a parity check matrix of an LDPC code in a communication system according to an exemplary embodiment of the present invention.

The parity check matrix “H” of the LDPC code includes eight columns and four rows, wherein the eight columns correspond to variable nodes v₁, v₂, v₃, v₄, v₅, v₆, v₇ and v₈, and the four rows correspond to check nodes c₁, c₂, c₃ and c₄. The value of “−1” in the parity check matrix “H” corresponds to the value of “0” in the conventional parity check matrix, and the value of “m” in the parity check matrix “H” corresponds to a value other than “0” in the conventional parity check matrix, that is, to a case where an edge is generated between a variable node and a check node.

Then, the decoder stores the message address ordering information of the edge message memory 935 and the message address ordering information of the Q_{c} memory 925 of FIG. 9, which correspond to indicators q₁, q₂, q₃ and q₄ representing each element of the parity check matrix “H,” in the message address memory 934 and the Q_{c} address memory 927. In this case, the message address ordering information stored in the Q_{c} address memory 927 may be expressed as Table 3 below, and the message address ordering information stored in the message address memory 934 may be expressed as Table 4 below. That is, Tables 3 and 4 show arrangement of edges and check nodes of the Q_{c} memory 925 and edge message memory 935 in the decoder. In this case, the decoder orders the addresses of the Q_{c} memory 925 at random, and then orders the addresses of the edge message memory 935 according to memory banks of the edge message memory 935.

TABLE 3

| Index | Bank 1 | Bank 2 |
|---|---|---|
| 0 | q1 | q4 |
| 1 | q3 | q2 |

TABLE 4

| Index | Bank 1 | Bank 2 |
|---|---|---|
| 0 | m1 | m2 |
| 1 | m5 | m3 |
| 2 | m7 | m4 |
| 3 | m8 | m6 |
| 4 | m10 | m9 |
| 5 | m12 | m11 |
| 6 | m14 | m13 |
| 7 | x | m15 |

In more detail with reference to Tables 3 and 4, edge m₁ in the parity check matrix “H,” is connected to node q₁, and is ordered in a memory bank according to this connection. Accordingly, edge m₁ and node q₁ are ordered in a first bank.

In this case, as described with reference to FIG. 9, the decoder determines the values of memory banks to be read from the edge message memory 935 and Q_{c} memory 925 according to addresses, while the control module 933 increases the indexes of the message address memory 934 and Q_{c} address memory 927, which store message address information and Q_{c} address information, respectively, by one at every cycle according to the status of the Q_{c} memory 925, as shown in Table 5. In addition, the decoder determines the value of a message indicator, that is, information representing whether or not the current message is the last message, while increasing the index of the indicator memory 929 by one at every cycle according to the status of the Q_{c} memory 925.

TABLE 5

| Index | Qc Memory Status |
|---|---|
| 1 | {q1, q2, q3, q4} |
| 2 | {q2, q3} |
| 3 | {q2, q3} |
| 4 | {q2, q3} |
| 5 | {q1, q2, q3, q4} |
| 6 | {q1, q3, q4} |
| 7 | {q1, q3} |
| 8 | {q1, q3} |
| 9 | {q1, q2, q3} |
| 10 | {q3, q4} |
| 11 | {q3, q4} |
| 12 | {q3, q4} |
| 13 | {q1, q2, q3, q4} |
| 14 | {q1, q2, q4} |
| 15 | {q1, q2, q4} |
| 16 | {q1, q2, q4} |
| 17 | {q1, q2, q3, q4} |
| 18 | {q1, q3, q4} |
| 19 | {q1} |
| 20 | {q1} |
| 21 | {q1, q2} |
| 22 | {q1, q2, q3, q4} |

TABLE 6

| Index | Bank 1 | Bank 2 |
|---|---|---|
| 1 | 1 | 1 |
| 2 | x | x |
| 3 | x | x |
| 4 | x | x |
| 5 | x | 2 |
| 6 | x | 1 |
| 7 | 2 | x |
| 8 | x | x |
| 9 | 1 | 2 |
| 10 | x | x |
| 11 | x | x |
| 12 | x | x |
| 13 | 1 | 2 |
| 14 | 2 | x |
| 15 | x | x |
| 16 | x | x |
| 17 | x | 2 |
| 18 | 2 | 1 |
| 19 | x | x |
| 20 | x | x |
| 21 | x | x |
| 22 | 1 | 1 |

TABLE 7

| Index | Bank 1 | Bank 2 |
|---|---|---|
| 1 | 1 | 1 |
| 2 | x | x |
| 3 | x | x |
| 4 | x | x |
| 5 | x | 2 |
| 6 | x | 3 |
| 7 | 3 | x |
| 8 | x | x |
| 9 | 2 | 4 |
| 10 | x | x |
| 11 | x | x |
| 12 | x | x |
| 13 | 4 | 5 |
| 14 | 5 | x |
| 15 | x | x |
| 16 | x | x |
| 17 | x | 6 |
| 18 | 6 | 7 |
| 19 | x | x |
| 20 | x | x |
| 21 | x | x |
| 22 | 7 | 8 |

TABLE 8

| Index | Bank 1 |
|---|---|
| 1 | 1 |
| 2 | 0 |
| 3 | 0 |
| 4 | 0 |
| 5 | 0 |
| 6 | 1 |
| 7 | 1 |
| 8 | 0 |
| 9 | 1 |
| 10 | 0 |
| 11 | 0 |
| 12 | 0 |
| 13 | 0 |
| 14 | 1 |
| 15 | 0 |
| 16 | 0 |
| 17 | 1 |
| 18 | 1 |
| 19 | 0 |
| 20 | 0 |
| 21 | 0 |
| 22 | 1 |

Table 6 shows the values of memory banks, which are stored in the Q_{c} address memory 927, to be read from the Q_{c} memory 925. Table 7 shows the values of memory banks, which are stored in the message address memory 934, to be read from the edge message memory 935. Table 8 shows message indicators stored in the indicator memory 929. In Tables 6 and 7, “x” represents that there is no edge message and that memory reading is not to be performed (i.e. no operation)

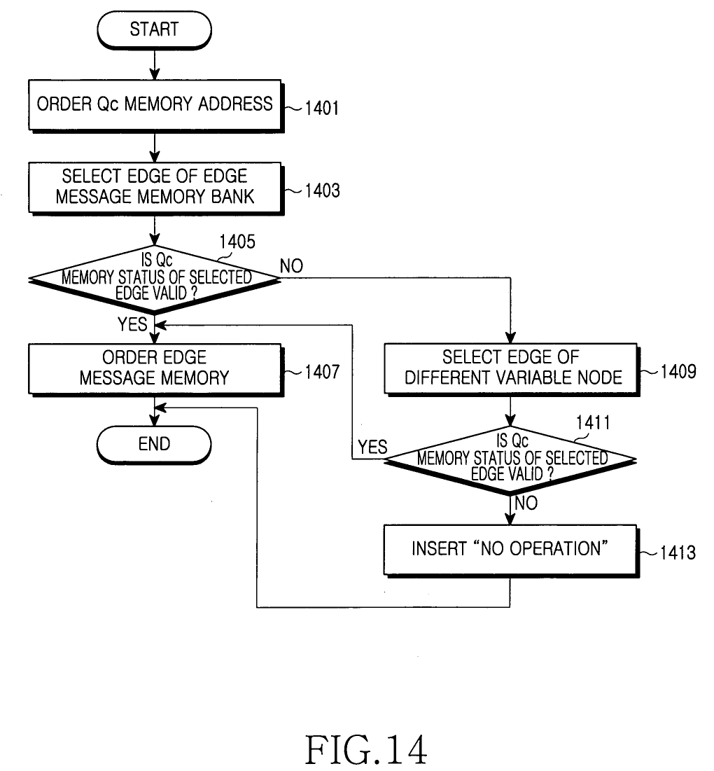

Hereinafter, the address ordering operation of the decoder in the communication system according to an exemplary embodiment of the present invention will be described in more detail with reference to FIG. 14.

FIG. 14 is a flowchart illustrating the address ordering operation of the decoder in the communication system according to an exemplary embodiment of the present invention.

In step 1401, the decoder orders the addresses of the Q_{c} memory at random, as described with reference to Tables 3 and 4. Then, in step 1403, the decoder selects an edge of an edge message memory bank according to an edge generated between a variable node and a check node in a parity check matrix “H.” Next, in step 1405, the decoder determines if the Q_{c} memory status of the selected edge is valid, as described with reference to Table 5. When it is determined in step 1405 that the Q_{c} memory status is valid, the decoder proceeds to step 1407. In step 1407, the decoder determines a value of a memory bank, which is stored in the Q_{c} address memory, to be read from the Q_{c} memory, determines a value of a memory bank, which is stored in the message address memory, to be read from the edge message memory, and orders addresses of the edge message memory, as described with reference to Tables 6 and 7.

In contrast, when it is determined in step 1405 that the Q_{c} memory status is invalid, the decoder proceeds to step 1409. In step 1409, the decoder selects an edge of another variable node.

Then, in step 1411, the decoder determines if the Q_{c} memory status of the selected edge is valid, as performed in step 1405. When it is determined in step 1411 that the Q_{c} memory status is valid, the decoder proceeds to step 1407. In contrast, when it is determined in step 1411 that the Q_{c} memory status is invalid, the decoder proceeds to step 1413. In step 1413, the decoder inserts “x” representing that there is no edge and that memory reading is not to be performed (i.e., “no operation”), as described with reference to Tables 6 and 7.

As described above, according to the present invention, an LDPC code is decoded through the message-passing algorithm using the variable node-based serial scheduling scheme, thereby increasing the data processing speed. Also, messages are processed not according to the degrees of nodes, but according to message indicators, and LDPC codes are decoded, thereby increasing the data processing speed. In addition, according to the present invention, the decoder of the LDPC code is implemented with one edge message memory and one node memory, thereby reducing the complexity of the receiver.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. An apparatus for receiving data in a communication system, the apparatus comprising:
a first memory for receiving data and storing input messages of respective check nodes in a low-density parity check (LDPC) matrix of the received data;
a second memory for storing a first summation value of all the input messages of the check nodes; and
a decoder for subtracting the input messages of the respective check nodes from the first summation value, and updating input messages of respective variable nodes corresponding to the check nodes.

2. The apparatus as claimed in claim 1, wherein the decoder comprises:
a subtractor for calculating first subtraction values by subtracting the input messages of the respective check nodes, corresponding to a first rotation number from a second summation value corresponding to the first rotation number; and
a first function processor for taking first inverse functions of the respective first subtraction values, and outputting resultant values as input messages of the respective variable nodes corresponding to the check nodes.

3. The apparatus as claimed in claim 2, wherein the decoder further comprises:
a module for storing a rotation number of messages passing between the check nodes and the variable nodes; and
a third memory for storing address information about the second summation value.

4. The apparatus as claimed in claim 2, wherein the first inverse function used in the first function processor is defined as:
$${F}^{- 1} ( x ) \text{:} {( log \frac{1 + {e}^{- x}}{1 - {e}^{- x}} )}^{- 1} .$$

5. The apparatus as claimed in claim 2, wherein the decoder comprises an adaptive variable processor, which updates input messages of check nodes for a second rotation number, with the input messages of the check nodes, by using the input messages of the respective variable nodes and an log likelihood ratio (LLR) value for a rotation number prior to the first rotation number, and generates a decoded information bit of the received data.

6. The apparatus as claimed in claim 5, wherein the decoder comprises a second function processor for taking second functions of the input messages of the updated check nodes, and outputting resultant values as input message values of the check nodes corresponding to the second rotation number, wherein the input message values of the check nodes corresponding to the second rotation number are stored in the first memory.

7. The apparatus as claimed in claim 6, wherein the decoder takes the second function of the first subtraction value, adds up a value of the second function and the input message values of the check nodes corresponding to the second rotation number, and stores a resultant value as a third summation value corresponding to the second rotation number in the second memory.

8. The apparatus as claimed in claim 7, wherein the second function used in the second function processor is defined as:
$$F ( x ) \text{:} log \frac{1 + {e}^{- x}}{1 - {e}^{- x}} .$$

9. A method for receiving data in a communication system, the method comprising the steps of:
receiving data and storing input messages of respective check nodes in a low-density parity check (LDPC) matrix of the received data;
adding up all of the input messages of the check nodes and storing a calculated first summation value; and
updating input messages of variable nodes corresponding to the respective check nodes, with values obtained by subtracting the input messages of the respective check nodes from the first summation value.

10. The method as claimed in claim 9, wherein the step of updating the input messages comprises the steps of:
calculating first subtraction values by subtracting input messages of respective check nodes corresponding to a first rotation number from a second summation value corresponding to the first rotation number; and
taking first inverse functions of the respective first subtraction values, and outputting resultant values as input messages of respective variable nodes corresponding to the check nodes.

11. The method as claimed in claim 10, further comprising the steps of:
storing a rotation number of message passing between the check nodes and the variable nodes; and
storing address information about the second summation values.

12. The method as claimed in claim 10, wherein the first inverse function is defined as:
$${F}^{- 1} ( x ) \text{:} {( log \frac{1 + {e}^{- x}}{1 - {e}^{- x}} )}^{- 1} .$$

13. The method as claimed in claim 10, further comprising the steps of:
updating input messages of check nodes for a second rotation number, with the input messages of the check nodes, by using the input messages of the respective variable nodes and an log likelihood ratio (LLR) value for a rotation number prior to the first rotation number; and
generating a decoded information bit of the received data.

14. The method as claimed in claim 13, further comprising a step of taking second functions of the input messages of the updated check nodes, and storing resultant values as input message values of the respective check nodes corresponding to the second rotation number.

15. The method as claimed in claim 14, further comprising a step of taking the second function of the first subtraction value, adding up a value of the second function and the input message values of the respective check nodes corresponding to the second rotation number, and storing a resultant value as a third summation value corresponding to the second rotation number.

16. The method as claimed in claim 15, wherein the second function is defined as:
$$F ( x ) \text{:} log \frac{1 + {e}^{- x}}{1 - {e}^{- x}} .$$
